(19) United States
(12) Patent Application Publication
(10) Pub. No.: US 2008/0258135 A1
(43) Pub. Date: Oct. 23, 2008

(54) SEMICONDUCTOR STRUCTURE HAVING PLURAL BACK-BARRIER LAYERS FOR IMPROVED CARRIER CONFINEMENT

(76) Inventors: William E. Hoke, Wayland, MA (US); Eduardo M. Chumbes, Andover, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 11/737,217

(22) Filed: Apr. 19, 2007

(51) Int. Cl. H01L 29/205

(52) U.S. Cl. 257/23; 257/E29.069; 257/E29.091; 257/E29.248

(57) ABSTRACT

A semiconductor structure having: a channel layer having a conductive channel therein; a pair of polarization generating layers; a spacer layer disposed between the pair of polarization generating layers. The polarization generating layers create polarization fields along a common, predetermined direction. Each one of the pair of polarizations layers may be InGaN; InAlGaN; or quaternary InₓAl_{y}Ga_{1-x-y}N and x is greater than or equal to y/2. The polarization generating layers create polarization fields along a common, predetermined direction constructively increasing the total polarization fields experienced by the channel layer to increase confinement of carriers in the conductive channel.

### TECHNICAL FIELD

This invention relates generally to semiconductor structure and semiconductor structures having a back-barrier layer to confine carriers.

### BACKGROUND AND SUMMARY

As is known in the art, quantum-wells are commonly used to confine carriers in transistor structures such as HEMTs (high electron mobility transistors) and FETs (field effect transistors). For example, in a conventional GaAs PHEMT (pseudomorphic HEMT), the low bandgap InGaAs channel layer is bounded on both sides by large bandgap AlGaAs barrier layers. The higher carrier energy in the AlGaAs barrier layers improves the confinement of carriers in the InGaAs well compared to the same structure without the AlGaAs barrier underneath the InGaAs well. This layer is often termed a back-barrier.

A nitride analog of the AlGaAs Barrier/InGaAs channel/AlGaAs Back-barrier/GaAs Buffer HEMT structure is the AlGaN Barrier/GaN channel/AlGaN Back-barrier/GaN Buffer structure. However, nitride materials exhibit significantly larger polarization fields than arsenide materials at heterojunctions. At AlGaN/GaN heterojunctions, the polarization difference between GaN and AlGaN causes electron accumulation in the underlying GaN layer. As shown in FIG. 1, carriers are favorably created in the GaN channel layer by the top AlGaN barrier but undesirable charge is also created in the GaN buffer layer. This deleterious second conduction channel degrades device performance due to poor current modulation and poor device pinch-off.

This problem has been addressed by inserting an ultrathin (˜10 Å), elastically strained InGaN back-barrier underneath the GaN channel layer to create the structure AlGaN Barrier/GaN channel/InGaN Back-barrier/GaN Buffer as shown in FIG. 2, see T. Palacios, A. Chakraborty, S. Heikman, S. Keller, S. P. DenBaars, and U. K. Mishra, IEEE Electron Device Letters Vol. 27, 2006, pp. 13-15. The direction of the polarization at a GaN/InGaN interface is opposite that of a GaN/AlGaN interface so electron charge does not accumulate in the underlying GaN buffer layer using an InGaN back-barrier. A one-dimensional Poisson-Schrödinger model has been used to calculate the effect on the band structure by the InGaN back-barrier. This model takes into consideration polarization and quantum effects. FIG. 3A shows a calculation of the conduction band edge in a GaN HEMT with and without a 10 Å In_{0.1}Ga_{0.9}N back-barrier layer. The presence of the InGaN layer raises the conduction band edge (solid line) above the same structure without InGaN (dashed line) at depths greater than 440 Å. FIG. 3B shows the corresponding charge profiles. Better confinement is observed with the InGaN back-barrier as the charge is negligible (10¹⁰ cm⁻³) at a depth of 480 Å with InGaN and 540 Å without InGaN.

FIGS. 4A and 4B, to be described in the detail description section below, show a limitation of the current approach. To further increase the polarization confinement, an InGaN layer with a higher indium concentration could be used. However as the calculations in FIGS. 4A and 4B indicate for a 10 Å In_{0.2}Ga_{0.8}N back-barrier, the higher indium concentration leads to a deep InGaN well (FIG. 4A) with a moderate density of carriers in the InGaN well (FIG. 4B). The peak carrier concentration in the 20% InGaN well in FIG. 4B (1×10¹⁶ cm⁻³) has been significantly increased from that of the 10% InGaN layer in FIG. 31B (1×10¹⁴ cm⁻³). Carriers in InGaN have poorer transport properties than GaN and will degrade device performance.

In accordance with the present invention, a semiconductor structure is provided having: a channel layer having a conductive channel therein. The structure includes: a pair of polarization generating layers; and a spacer layer disposed between the pair of polarization generating layers. The polarization generating layers create polarization fields along a common, predetermined direction increasing the total polarization fields experienced by the channel layer to increase confinement of carriers in the conductive channel. Furthermore by using multiple InGaN layers, the indium concentration in an individual layer can be keep low enough to prevent the formation of a deep well with charge accumulation in the well.

In one embodiment, one of the pair of polarization generating layers is InGaN.

In one embodiment, one of the pair of polarization generating layers is InAlGaN.

In one embodiment, one of the pair of polarization generating layers is quaternary InₓAl_{y}Ga_{1-x-y}N.

In one embodiment, one of the polarization generating layers is quaternary InₓAl_{y}Ga_{1-x-y}N, where x is greater than or equal to y/2.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagrammatical cross sectional sketch of an AlGaN Barrier/GaN Channel/AlGaN Back-barrier/GaN Buffer structure with the direction of the total polarization field indicated at the AlGaN/GaN heterojunctions and with conduction channels created in both the GaN channel layer and the GaN buffer layer according to the PRIOR ART;

FIG. 2 is a diagrammatical cross sectional sketch of an AlGaN Barrier/GaN Channel/InGaN Back-barrier/GaN Buffer structure with the direction of the total polarization field due to the InGaN back-barrier opposite that of AlGaN leading to confinement of carriers in the GaN channel layer and with a conduction channel formed in the InGaN layer depending on its composition and thickness according to the PRIOR ART.

FIG. 3A shows a conduction band profile of a conventional 180 Å Al_{0.25}Ga_{0.75}N/GaN HEMT (dashed curve) and a 180 Å Al_{0.25}Ga_{0.75}N/250 Å GaN/10 Å In_{0.1}Ga_{0.9}N/GaN HEMT counterpart (solid curve). The vertical dotted lines demarcate the layer boundaries for the latter structures. The InGaN layer has raised the conduction band edge for depths greater than 440 Å, providing improved carrier confinement in the GaN channel layer;

FIG. 3B shows corresponding mobile charge distributions for the two HEMT structures demonstrating the improved carrier confinement (solid curve) due to the thin InGaN layer with negligible charge (10¹⁰ cm⁻³) beyond a depth of 480 Å for InGaN and 540 Å without InGaN. Note the charge formed in the well of the InGaN back-barrier is negligible (roughly a factor 10⁵ lower than the peak charge density at a depth of 180 Å corresponding to the HEMT mobile carriers);

FIG. 4A shows a conduction band profile of a conventional 180 Å Al_{0.25}Ga_{0.75}N/GaN HEMT (dashed curve) and a 180 Å Al_{0.25}Ga_{0.75}N/250 Å GaN/10 Å In_{0.2}Ga_{0.8}N/GaN HEMT (solid curve). Compared to FIG. 3A, the higher indium concentration has further raised the conduction band edge but the well of the InGaN back-barrier is also much deeper;

FIG. 4B shows a corresponding mobile charge distribution for the In_{0.2}Ga_{0.8}N back-barrier HEMT; note that the deeper well of the InGaN back-barrier has significantly increased the carrier density in the InGaN layer which is a parasitic conduction path;

FIG. 5 is a diagrammatical cross sectional sketch of an AlGaN/GaN HEMT structure containing 2 InGaN back-barrier layers, the polarization fields due to the InGaN layers constructively add according to the invention;

FIG. 6A shows a conduction band profile of a conventional 180 Å Al_{0.25}Ga_{0.75}N/GaN HEMT, a 180 Å Al_{0.25}Ga_{0.75}N/250 Å GaN/10 Å In_{0.2}Ga_{0.8}N/GaN HEMT, and a 180 Å Al_{0.25}Ga_{0.75}N/190 Å GaN/10 Å In_{0.05}Ga_{0.95}N/50 Å GaN/10 Å In_{0.15}Ga_{0.85}N/GaN HEMT, as labeled in FIG. 6A; note that the sum of the polarization effect (FIG. 6A) on the conduction band edge at depths greater than 440 Å of the 5% and 15% InGaN layers is equivalent to a single 20% InGaN layer;

FIG. 6B shows a corresponding mobile charge distribution for the structures in FIG, 6A and shows that the charge accumulation in the InGaN layers is significantly less for the structure with In_{0.05}Ga_{0.95}N and In_{0.15}Ga_{0.85}N layers than the structure with the In_{0.2}Ga_{0.8}N layer. Furthermore better confinement is obtained with the structure containing two InGaN layers compared to one InGaN layer in that the value for N(cm⁻³) drops to 10¹⁰ cm⁻³ at a depth of 465 Å for the former and 484 Å for the latter structure; and

FIG. 7 is a diagrammatical cross sectional sketch of an GaN FET structure having 2 InGaN back-barrier layers, the polarization fields due to the InGaN layers constructively add according to the invention.

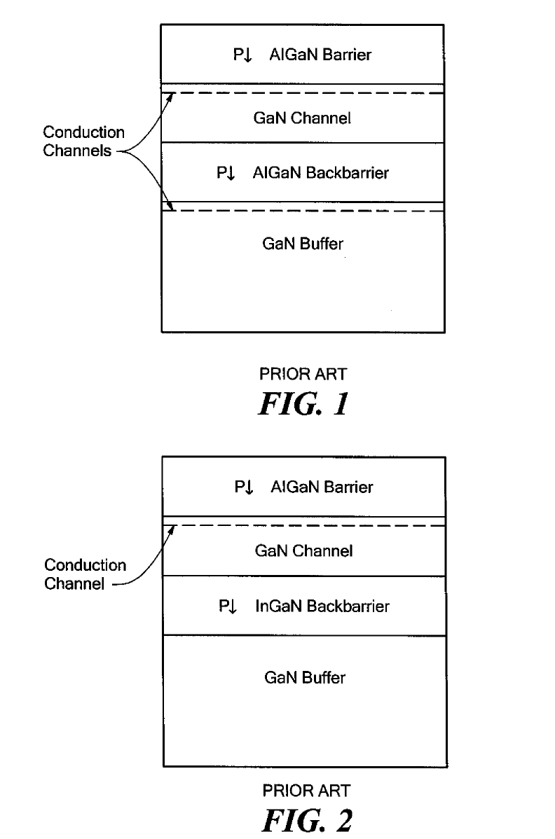

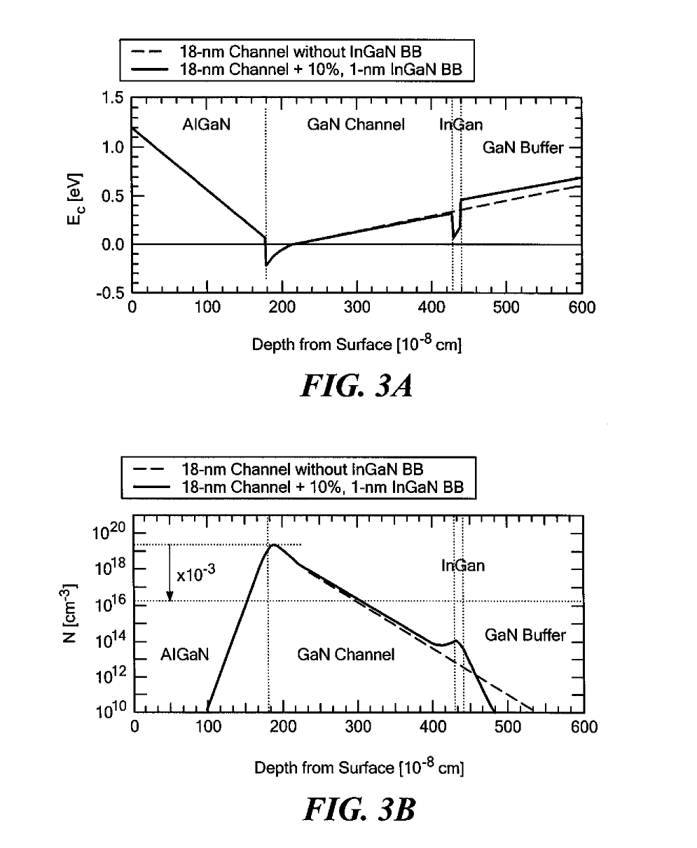

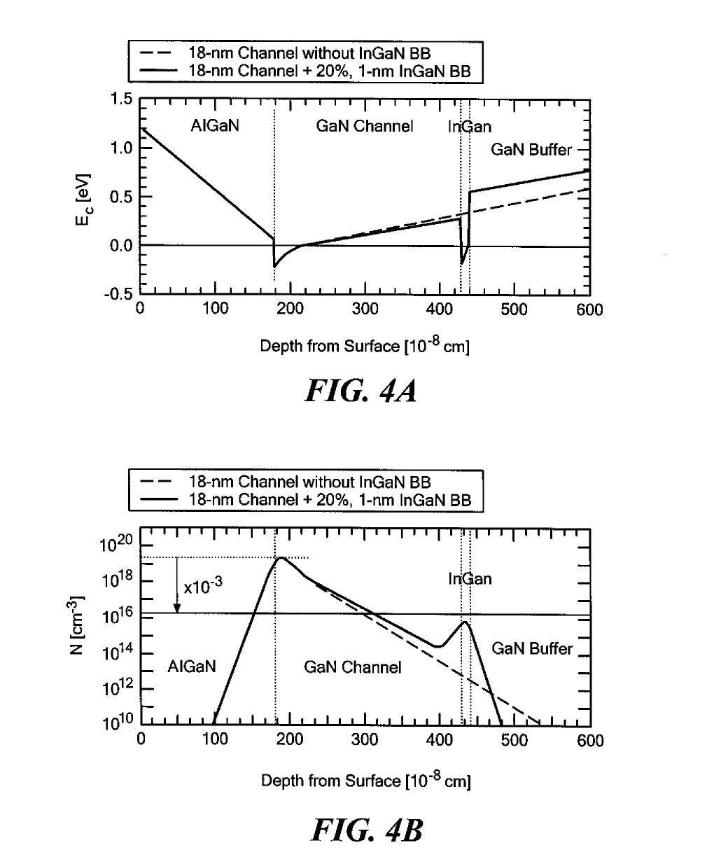

Like reference symbols in the various drawings indicate like elements.

### DETAILED DESCRIPTION

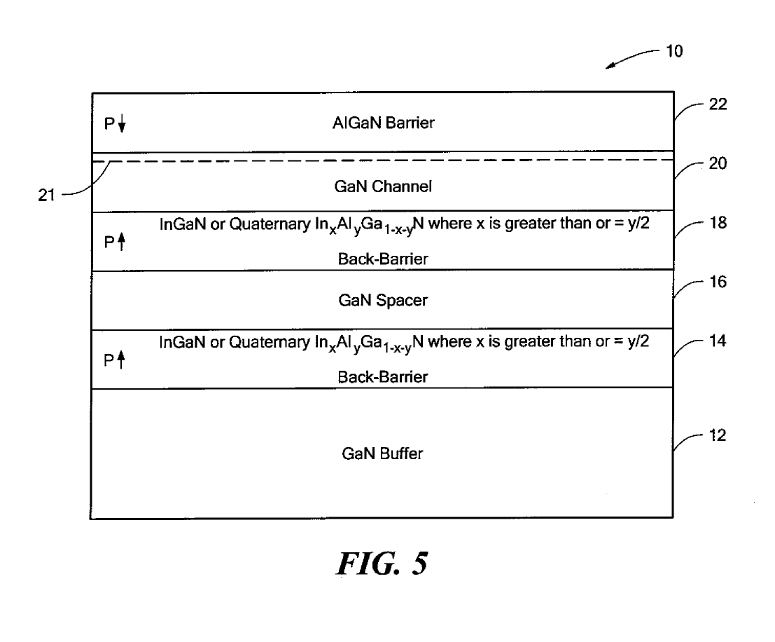

Referring now to FIG. 5, a semiconductor structure 10 is shown. Here the semiconductor structure 10 is suitable for a HEMT (i.e., High Electron Mobility Transistor) and includes: a GaN buffer layer 12; a plurality of, here two, InGaN back-barrier layers 14, 18 on the GaN buffer layer 12, with such pair of back-barrier layers 14, 18 being separated by a spacer layer 16, here a GaN spacer layer; a GaN channel layer 20; and an AlGaN barrier layer 22 on the channel layer.

Back-barrier layer 14 is here, for example, InGaN or quaternary InₓAl_{y}Ga_{1-x-y}N, where here x is greater than or equal to y/2.

Back-barrier layer 18 is here, for example, InGaN or quaternary InₓAl_{y}Ga_{1-x-y}N, where here x is greater than or equal to 2y.

It is noted that one of the pair of back-barrier layers 14, 18 may be for example, InGaN, while the other one of the back-barrier layers 14, 18 may be of a different material, for example, quaternary InₓAl_{y}Ga_{1-x-y}N.

It is also noted that a heterojunction is formed between back-barrier layer 14 and the GaN buffer layer 12 and a heterojunction is formed between back-barrier layer 14 and spacer layer 16 resulting in an electric field or polarization vector P along a vertical direction, as indicated by the arrow shown in back-barrier layer 14.

It is also noted that a heterojunction is formed between back-barrier layer 18 and the spacer layer 16 and a heterojunction is formed between back-barrier layer 18 and the channel layer 20 resulting in an electric field or polarization vector P along a vertical direction, as indicated by the arrow shown in back-barrier layer 18.

Here, the thicknesses of the layers 14, 16, 18, 20 and 22 are in the ranges of: 5-100 Angstroms, 10-500 Angstroms, 5-100 Angstroms, 20-1000 Angstroms, and 50-1000 Angstroms, respectively.

It is noted that the channel layer 20 has a conductive channel 21 therein, and the barrier layer 22 is on one surface of the channel layer.

A polarization field, P, having a direction indicated by the arrow, is generated in the barrier layer 22 along a first predetermined direction, here vertically downward, normal to said surface of the channel barrier layer 22.

As noted above, the back-barrier layers 14, 18 are elastically strained InGaN back-barrier layers 14, 18. The GaN spacer layer 16 is disposed between, and forms heterojunctions with, the pair of back-barrier layers 14, 18. The pair of back-barrier layers 14, 18 form heterojunction described above and thereby create polarization fields along a common, predetermined direction, here vertically upward direction, opposite to said first direction (i.e., opposite to the direction of the polarization in the barrier layer 22) as indicated by the vertically upward arrows in the back-barrier layers 14, 18. Thus, the polarizations generated in the pair of back-barrier layer 14, 18 add constructively thereby increasing the total polarization fields experienced by the channel layer 20 to increase confinement of carriers in the conductive channel 21.

It is noted that there are two components to the polarization related to the InGaN: polarization from the InGaN being strained (piezoelectric) and natural or spontaneous polarization. Piezoelectric polarization is created in InGaN since it is elastically strained to lattice match with GaN. Therefore InGaN (being larger than GaN) is compressed. It has been determined that when InGaN is compressed its piezoelectric polarization points up. When it is under tensile strain, its piezoelectric polarization points down. (AlGaN is under tensile strain and has its piezoelectric polarization vector pointing down.) Every material also has a natural polarization due to a difference in the spatial location of positive charge (from the atomic nuclei) and the electronic charge. When crossing a heterojunction (going from one material to another) there is a change in spontaneous polarization. The polarization directions will be automatically correct by growing the layers in the order specified herein (i.e. InGaN or InAlGaN formed on GaN, then GaN on the InGaN or InAlGaN then GaN on InGaN or InAlGaN). Note also that the specification for AlInGaN with the indium concentration being more than half the Al concentration also ensures that the total (sum of piezoelectric and spontaneous polarization) polarization vector points up when using AlInGaN.

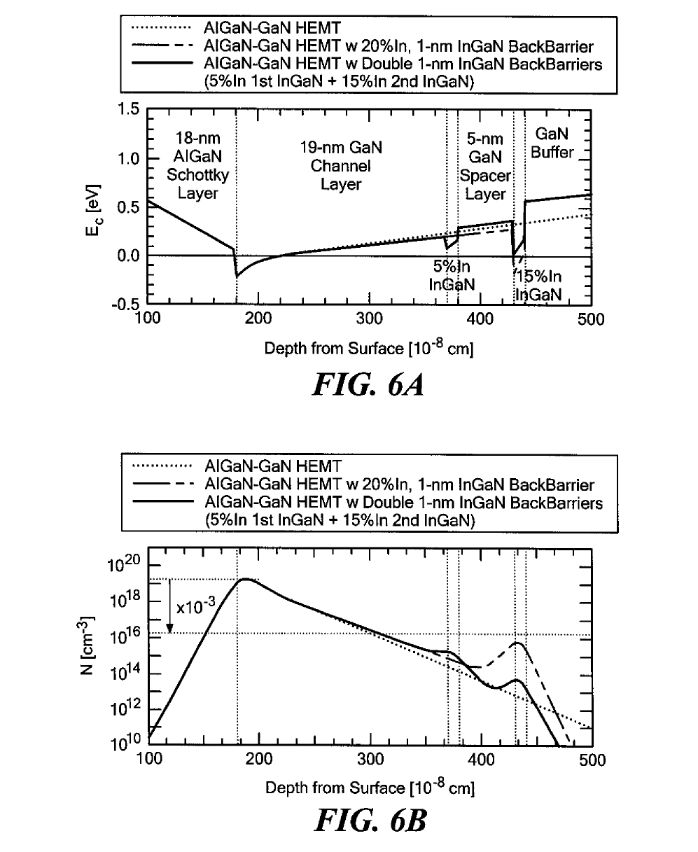

In view of the limitations with the single back-barrier, the structures in FIG. 5 uses multiple, elastically strained ultrathin back-barriers layers 14, 18. By stacking heterojunctions, as schematically shown in FIG. 5 for two back-barrier layers 14, 18, additional polarization fields are created at these new heterojunctions which point in the same direction, constructively increasing the total polarization field experienced by the GaN channel layer resulting in improved carrier confinement in the GaN channel layer. Furthermore by using multiple back-barriers, the indium concentration in an individual layer can be kept low enough to prevent the formation of a deep well with charge accumulation in the well. The calculations in FIGS. 6A and 6B demonstrate the invention. In FIG. 6A, the polarization effect on the conduction band edge at depths greater than 440 Å of two InGaN back-barriers with indium concentrations of 5% and 15% is the same as one 20% InGaN layer. However, FIG. 6B shows that the two InGaN backbarriers create better confinement with less carrier accumulation in the InGaN layers than a single 20% InGaN back-barrier.

Due to the additive nature of the polarization effect, more than 2 InGaN back-barriers could be used for further channel confinement. Indeed, one could consider an InGaN/GaN superlattice-type of structure.

Some additional benefits of this invention should be noted.

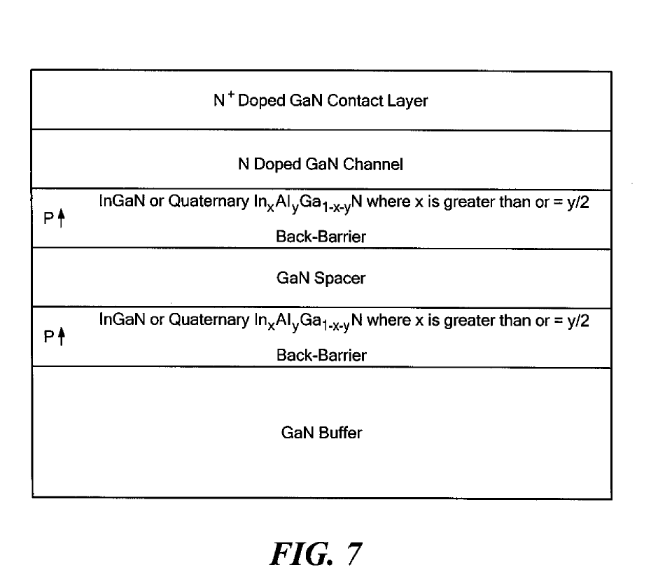

1. The discussion has considered the GaN HEMT structure. The invention is not limited to this structure. For example, a GaN FET (FIG. 7) would benefit by stacked InGaN back-barriers. Thus, here a doped GaN channel is used with a doped channel contact layer on the doped channel. Ohmic contacts, not shown, are in contact with the doped channel contact layer. A gate electrode, not shown, is in contact with the doped channel layer after a recess is made through the contact layer

2. The epitaxial growth of InGaN with increasing indium content becomes more difficult due to high crystal strain, surface segregation, and reduced thermal stability. With the invention, the indium concentration in an individual InGaN layer can be reduced, facilitating growth of high quality material.

3. The layer structures can be grown by various techniques. For example, by either molecular beam epitaxy (MBE) and metalorganic chemical vapor deposition (MOCVD), for example.

4. A variation of the above description is to incorporate aluminum into the InGaN back-barrier layers 14, 18 as noted above, to create the quaternary InₓAl_{y}Ga_{1-x-y}N back-barriers. With the indium concentration greater than one-half the aluminum concentration, the direction of the polarization field will be the same as with InGaN. The addition of aluminum, however, with raise the bandgap and further decrease the charge in the back-barrier layer.

A number of embodiments of the invention have been described. For example, additional pairs of back-barrier layers separated by spacers may be stacked beneath the channel layer 20. Thus, N back-barriers layers may be used with each pair thereof having a corresponding one of N-1 spacer layers therebetween, where N is an integer greater than 2.

Nevertheless, it will be understood that various modifications may be made without departing from the spirit and scope of the invention. Accordingly, other embodiments are within the scope of the following claims.

What is claimed is:

1. A semiconductor structure comprising:
a channel layer;
a pair of polarization generating layers;
a spacer layer disposed between the pair of polarization generating layers; and
wherein the polarization generating layers create polarization fields along a common, predetermined direction

2. The structure recited in claim 1 wherein one of the pair of polarization generating layers is InGaN.

3. The structure recited in claim 1 wherein one of the pair of polarization generating layers is quaternary InₓAl_{y}Ga_{1-x-y}N.

4. The structure recited in claim 1 wherein said one of the pair of polarization layers is quaternary InₓAl_{y}Ga_{1-x-y}N and wherein x is greater than or equal to y/2.

5. A semiconductor structure, comprising:
a GaN layer;
a plurality of back-barrier layers on the GaN layer, pairs of such back-barrier layers being separated by a spacer layer;
a channel layer on and forming a heterojunction with one of the back-barrier layers.

6. The semiconductor structure recited in claim 5 wherein the back-barriers layers are InGaN.

7. The semiconductor structure recited in claim 5 wherein the back-barrier layers are quaternary InₓAl_{y}Ga_{1-x-y}N.

8. The semiconductor structure recited in claim 7 wherein x is greater than or equal to y/2.

9. A semiconductor structure, comprising:
a channel layer having a conductive channel therein;
at least a pair of back-barrier layers on a surface of the channel layer, one of such pair of back-barrier layers forming a heterojunction with the channel layer;
a GaN layer disposed between, and forming heterojunctions with, the pair of backbarrier layers;
wherein the pair of back-barrier layers create polarization fields along a common, predetermined direction constructively increasing the total polarization fields experienced by the channel layer to increase confinement of carriers in the conductive channel.

10. A semiconductor structure, comprising:
a channel layer;
at least a pair of polarization generating layers, one of such pair of polarization generating layers forming a heterojunction with the channel layer;
a spacer layer disposed between, and forming heterojunctions with, the pair of polarization generating layers;
wherein the polarization generating layers create polarization fields along a common, predetermined direction.

11. The semiconductor structure recited in claim 10 wherein the spacer layer is GaN.

12. The semiconductor structure recited in claim 10 wherein the channel layer is GaN.

13. The semiconductor structure recited in claim 10 wherein one of the polarization generating layers is InGaN.

14. The semiconductor structure recited in claim 10 wherein one of the polarization generating layers is quaternary InₓAl_{y}Ga_{1-x-y}N.

15. The semiconductor structure recited in claim 14 wherein the In concentration, x is greater than or equal to y/2.

16. A semiconductor structure, comprising:
a channel layer;
a pair of back-barrier layers on a surface of the channel layer, one of such pair of back-barrier layers forming a heterojunction with the channel layer;
a layer forming heterojunctions with the pair of back-barrier layers;
wherein the pair of back-barrier layers create polarization fields along a common, predetermined direction.

17. The semiconductor structure recited in claim 16 including an additional layer; and wherein a first heterojunction is formed between the additional layer and another one of the pair of back-barrier layer.
